(19) United States
(12) Patent Application Publication
(10) Pub. No.: US 2026/0164833 A1
(43) Pub. Date: Jun. 11, 2026

(54) IMAGE SENSOR

(71) Applicant: Samsung Electronics Co., Ltd., Suwon-si (KR)

(72) Inventors: Ingyu HYUN, Suwon-si (KR); WONHYEOK KIM, Suwon-si (KR); UISIK KIM, Suwon-si (KR); ILJOONG KIM, Suwon-si (KR)

(21) Appl. No.: 19/251,539

(22) Filed: Jun. 26, 2025

(30) Foreign Application Priority Data
Dec. 10, 2024 (KR) 10-2024-0182463

(51) Int. Cl. H10F 39/00

(52) U.S. Cl. CPC H10F 39/811; H10F 39/805; H10F 39/807

(57) ABSTRACT

An image sensor includes a substrate comprising a first surface and a second surface opposing the first surface, a first pixel region comprising a first photodiode, a second pixel region comprising a second photodiode, a separation structure between the first photodiode and the second photodiode and penetrating the substrate, a first trench penetrating a part of the substrate from the first surface in the first pixel region, a first transfer gate electrode comprising a first part in the first trench and a second part protruded from the first surface in the first pixel region and a protective pattern comprising a first surface at the same level of the first surface of the substrate and a second surface opposing the first surface of the protective pattern, wherein a width of the first surface of the protective pattern in a first direction parallel to the first surface of the substrate in a vertical view is greater than a width of the first part of the first transfer gate electrode at the first surface in the first direction in the vertical view, and wherein the image sensor is configured to receive light from the second surface of the substrate.

### CROSS-REFERENCE TO RELATED APPLICATIONS

This U.S. non-provisional patent application claims priority under 35 U.S.C. § 119 to Korean Patent Application No. 10-2024-0182463 filed on Dec. 10, 2024, in the Korean Intellectual Property Office, the entire contents of which are hereby incorporated by reference.

### BACKGROUND OF THE INVENTION

The inventive concept relates to an image sensor, and more in detail, relates to an image sensor including a transfer gate electrode.

An image sensor may convert an optical image into electrical signals. Image sensors may be categorized as a charge coupled device (CCD) image sensor or complementary metal-oxide-semiconductor (CMOS) image sensor (CIS). The CIS may include a plurality of pixels disposed two-dimensionally. Each of, or at least one of, the pixels may include a photodiode (PD). The photodiode may be configured to convert incident light into an electrical signal.

### SUMMARY

An object of the inventive concept is to provide an image sensor with improved electrical characteristics.

The problem to be solved by the inventive concept is not limited to the problems mentioned above, and other problems not mentioned may be clearly understood by those skilled in the art from the description below.

An image sensor according to some embodiments of the inventive concept may include a substrate comprising a first surface and a second surface opposing the first surface, a first pixel region comprising a first photodiode, a second pixel region comprising a second photodiode, a separation structure between the first photodiode and the second photodiode and penetrating the substrate, a first trench penetrating a part of the substrate from the first surface in the first pixel region, a first transfer gate electrode comprising a first part in the first trench and a second part protruded from the first surface in the first pixel region and a protective pattern comprising a first surface at the same level as the first surface of the substrate and a second surface opposing the first surface of the protective pattern, wherein a width of the first surface of the protective pattern in a first direction parallel to the first surface of the substrate in a vertical view is greater than a width of the first part of the first transfer gate electrode at the first surface in the first direction in the vertical view, and wherein the image sensor is configured to receive light from the second surface of the substrate.

An image sensor according to some embodiments of the inventive concept may include a substrate comprising a first surface and a second surface opposing the first surface, a first pixel region comprising a first photodiode, a second pixel region comprising a second photodiode, a third pixel region comprising a third photodiode, a fourth pixel region comprising a fourth photodiode, a floating diffusion region configured to store charges generated by the first to fourth photodiodes, a separation structure separating the first to fourth photodiodes to each other and penetrating the substrate, a first trench penetrating a part of the substrate from the first surface in the first pixel region, a first transfer gate electrode comprising a first part in the first trench and a second part protruded from the first surface in the first pixel region and a protective pattern comprising a first surface at the same level as the first surface of the substrate and a second surface opposing the first surface of the protective pattern, wherein a width of the first surface of the protective pattern in a first direction parallel to the first surface of the substrate in a vertical view is greater than a width of the first part of the first transfer gate electrode at the first surface in the first direction in the vertical view, wherein the first to fourth photodiodes are sequentially arranged in a clockwise direction in a plan view, and wherein the image sensor is configured to receive light from the second surface of the substrate.

An image sensor according to some embodiments of the inventive concept may include a substrate comprising a first surface and a second surface opposing the first surface, a first pixel region comprising a first photodiode, a second pixel region comprising a second photodiode, a separation structure between the first photodiode and the second photodiode and penetrating the substrate, a first trench penetrating a part of the substrate from the first surface in the first pixel region, a first transfer gate electrode comprising a first part in the first trench and a second part protruded from the first surface in the first pixel region and a protective pattern comprising a first surface at the same level as the first surface of the substrate and a second surface opposing the first surface of the protective pattern, wherein a width of the second surface of the protective pattern in a first direction in a vertical view is greater than a width of the first part of the first transfer gate electrode at a level of the second surface of the protective pattern in the first direction in the vertical view, and wherein the image sensor is configured to receive light from the second surface of the substrate.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of an image sensor according to some embodiments of the inventive concept.

FIG. 2 is a cross-sectional view taken along line A-A′ of FIG. 1.

FIG. 3 is a cross-sectional view taken along line B-B′ of FIG. 1.

FIG. 4 is an enlarged view of portion ‘CU1’ of FIG. 2.

FIG. 5 is a plan view of an image sensor according to some embodiments of the inventive concept.

FIG. 6 is a cross-sectional view taken along line C-C′ of FIG. 5.

FIGS. 7, 8, 9, 10, 11, 12, and 13 are cross-sectional views illustrating a manufacturing process of an image sensor according to some embodiments of the inventive concept.

### DETAILED DESCRIPTION

Hereinafter, the inventive concept will be described in detail by describing embodiments of the inventive concept with reference to the attached drawings.

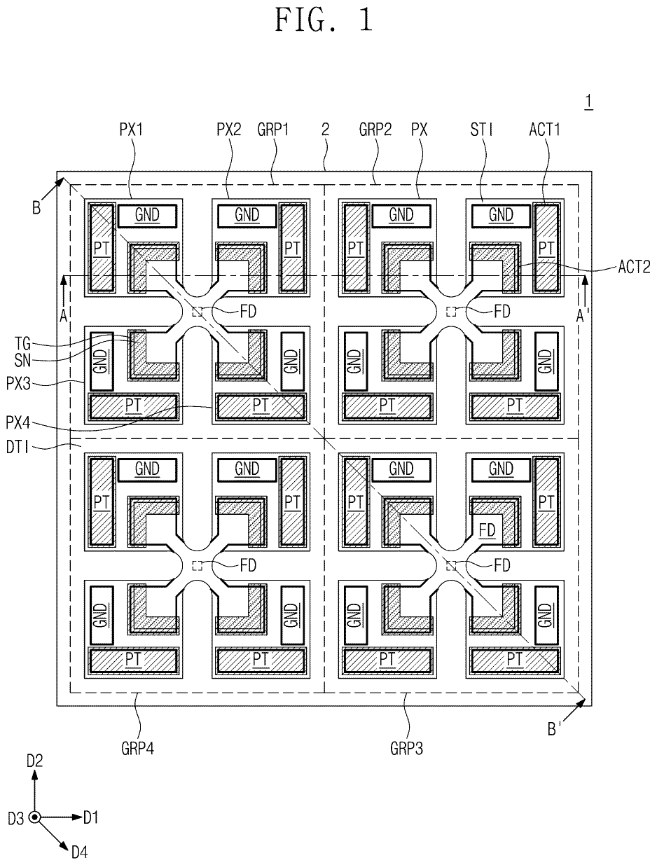

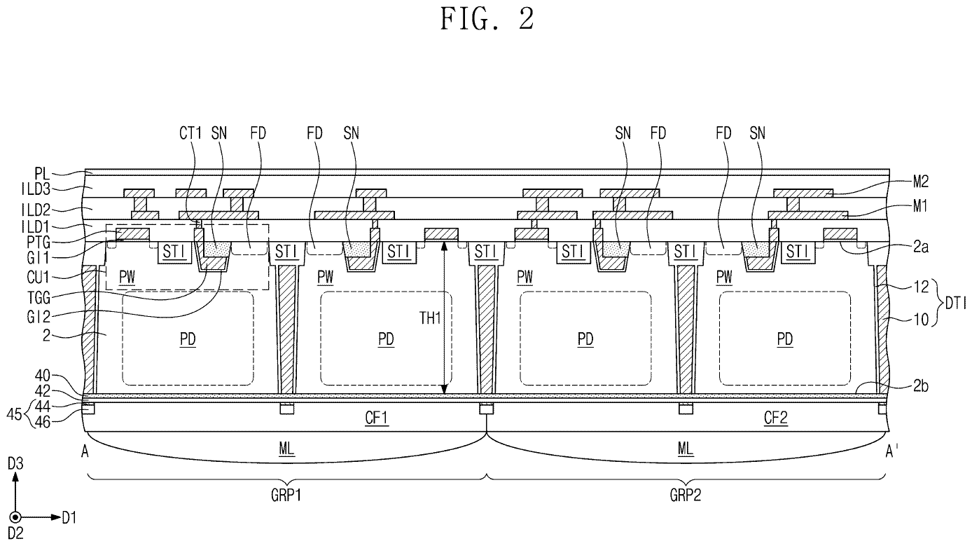

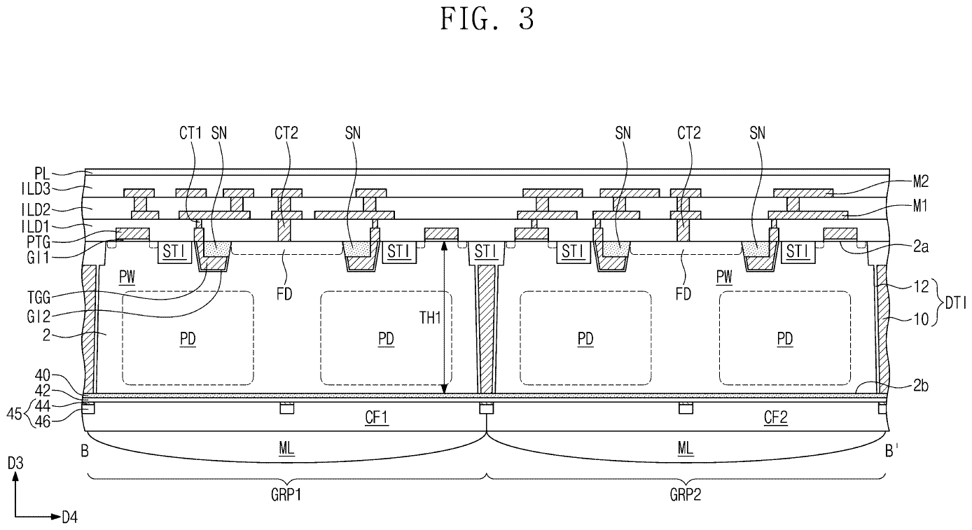

FIG. 1 is a plan view of an image sensor according to some embodiments of the inventive concept. FIG. 2 is a cross-sectional view taken along line A-A′ of FIG. 1. FIG. 3 is a cross-sectional view taken along line B-B′ of FIG. 1.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “constant,” “flat,” “symmetry,” “parallel,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality.

Referring to FIGS. 1 to 3, an image sensor 1 according to some embodiments of the inventive concept may include a substrate 2. The substrate 2 may include a first surface 2a and a second surface 2b facing away from each other. The first surface 2a and the second surface 2b are parallel to each other. The first surface 2a and the second surface 2b may constitute major planar surfaces of the substrate 2, specifically the top surface and bottom surface of the substrate 2, excluding recessed features such as grooves or holes formed therein, whereas the total surface may include all exposed areas, including the surfaces of such recessed features. Light may be incident into the substrate 2 through the second surface 2b. In this specification, the first surface 2a may correspond to a front surface of the substrate 2. The second surface 2b may correspond to a back surface of the substrate 2. The substrate 2 may be a single crystal wafer or an epitaxial layer or a silicon on insulator (SOI) substrate containing silicon and/or germanium.

In this specification, a first direction D1 is defined as a direction parallel to the first surface 2a of the substrate 2. A second direction D2 is defined as a direction parallel to the first surface 2a of the substrate 2 and perpendicular to the first direction D1. A third direction D3 is defined as a direction perpendicular to the first surface 2a of the substrate 2. A fourth direction D4 is defined as a direction that is parallel to the first surface 2a of the substrate 2 and intersects the first direction D1 and the second direction D2.

In detail, the image sensor 1 according to some embodiments of the inventive concept may include first to fourth pixel groups GRP1 to GRP4 disposed clockwise on the substrate 2. The first pixel group GRP1 and the second pixel group GRP2 may be adjacent to each other in the first direction D1. The second pixel group GRP2 and the third pixel group GRP3 may be adjacent to each other in the second direction D2. The third pixel group GRP3 and the fourth pixel group GRP4 may be adjacent to each other in the first direction D1. The first pixel group GRP1 and the fourth pixel group GRP4 may be adjacent to each other in the second direction D2. The first pixel group GRP1 to the fourth pixel group GRP4 may be separated by a separation structure DTI to be described later.

Each of the first pixel group GRP1 to the fourth pixel group GRP4 may include a plurality of pixel regions (or photodiode region) PX and photodiodes (or photodetectors) PD in the pixel regions PX. In an example, the pixel regions may include first to fourth pixel regions PX1 to PX4 in each of the first to fourth pixel groups GRP1 to GRP4. In an example, the plurality of photodiodes PD may be separated from each other by the separation structure DTI.

Each of the first to fourth pixel groups GRP1 to GRP4 may be a four shared pixel structure, where four pixels share pixel transistors PT. Alternatively, the structure may be “eight shared” or “sixteen shared”, where two or four pixel groups share the pixel transistors PT. The pixel transistors PT may include a reset transistor, a source follower transistor, a dual conversion gain transistor, and a selection transistor. For example, the reset transistor, source follower transistor, dual conversion gain transistor, or selection transistor may be disposed on the first pixel region PX 1 in each of the first to fourth pixel groups GRP1 to GRP4. In an example, the source follower transistor, selection transistor, and reset transistor may be disposed on the first pixel region PX1, the second pixel region PX2, and the third pixel region PX3, respectively.

Each of the plurality of pixel regions PX may include a transfer transistor TG. Each of the pixel groups may have a floating diffusion region FD and at least two floating diffusion regions among four floating diffusion regions in the first to fourth pixel groups may be connected to each other. For example, the floating diffusion region FD of the first pixel group GRP1 and the floating diffusion region FD of the second pixel group GRP2 may be connected to each other, the floating diffusion region FD of the first pixel group GRP1 and the floating diffusion region FD of the fourth pixel group GRP4 may be connected to each other, or four floating diffusion regions FD of the first to fourth pixel groups, GRP1 to GRP4, are connected to each other. In some embodiments, pixel groups which floating diffusion regions are connected to each other share a single ground region GND and the single ground region GND can be disposed in any one of locations marked ‘GND’ in FIG. 1.

Referring again to FIGS. 2 and 3, a photodiode PD may be disposed in (or with) the substrate 2. A well region PW may be disposed between the photodiode PD and the first surface 2a. The well region PW and the substrate 2 may be doped with, for example, a first impurity (charge carrier dopants) to have a first conductive type. The first impurity may be, for example, boron. The first conductive type may be, for example, P type. A concentration of the first impurity doped in the well region PW may be equal to or greater than a concentration of the impurity doped in the substrate 2.

The photodiode PD may be doped with a second impurity to have a second conductive type opposite to the first conductive type. The second impurity may be, for example, phosphorus or arsenic. The second conductive type may be, for example, N type. An N-type semiconductor region of the photodiode PD may form a PN junction with a P-type semiconductor region of the surrounding substrate 2 and/or the well region PW to form a photodiode, and when light is incident, electron-hole pairs may be generated by the PN junction.

In the substrate 2, the separation structure DTI that separates the first pixel group GRP1 to the fourth pixel group GRP4 and the photodiodes PD in the first pixel group GRP1 to the fourth pixel group GRP4 from each other. The separation structure DTI may penetrate the substrate 2. A width of the separation structure DTI may narrow from the first surface 2a to the second surface 2b.

The separation structure DTI may include a first isolation pattern 10 and a second isolation pattern 12. The first isolation pattern 10 may be disposed to be spaced apart from the substrate 2. The first isolation pattern 10 may include a conductive material having a different refractive index from that of the substrate 2. The first isolation pattern 10 may include, for example, polysilicon or metal doped with impurities.

The second isolation pattern 12 may be interposed between the first isolation pattern 10 and the substrate 2. The second isolation pattern 12 may include an insulating material having a different refractive index from that of the substrate 2. For example, each of the second isolation pattern 12 may include silicon oxide.

The first isolation pattern 10 may be applied with a negative bias voltage. The first isolation pattern 10 may function as a common bias line. For example, the plurality of first isolation patterns 10 may be biased by the same electrical potential. As a result, holes that may exist on a surface of the substrate 2 in contact with the separation structure DTI may be captured, thereby improving dark current characteristics.

The device isolation portion STI may be disposed on (or at) the first surface 2a of the substrate 2.

According to some embodiments, the above-described separation structure DTI may be provided on the device isolation portion STI.

According to some embodiments, the device isolation portion STI and the separation structure DTI may be formed of the same material. For example, an interface may not be distinguished between the device isolation portion STI and the separation structure DTI. For example, there may be no interface between the device isolation portion STI and the second isolation pattern 12. In this case, a content of the material included in the device isolation portion STI may be different from a concentration of a material included in the separation structure DTI. For example, the content of the material may refer to the content of silicon oxide contained in the device isolation portion STI and the separation structure DTI. In one embodiment, a single material (e.g., silicon oxide) may have two distinct compositions (e.g., stoichiometric compositions), and the device isolation portion STI and the separation structure DTI may each include the material in a different composition.

Hereinafter, an explanation of pixel gate electrode PTG, which is part of the pixel transistor PT, will now be provided. The pixel gate electrode PTG may be provided on the first surface 2a of the substrate 2. The pixel gate electrode PTG may include polysilicon doped with impurities, a conductive metal nitride, a conductive metal silicide, a conductive metal oxide, or a combination thereof. The first gate insulating pattern GI1 may be interposed between the pixel gate electrode PTG and the substrate 2.

As shown in FIG. 3, the floating diffusion region FD may be provided on the first surface 2a of the substrate 2.

Although not shown, according to some embodiments of the inventive concept, the separation structure DTI may be disposed on the floating diffusion region FD. In this case, the separation structure DTI may be spaced apart from the floating diffusion region FD.

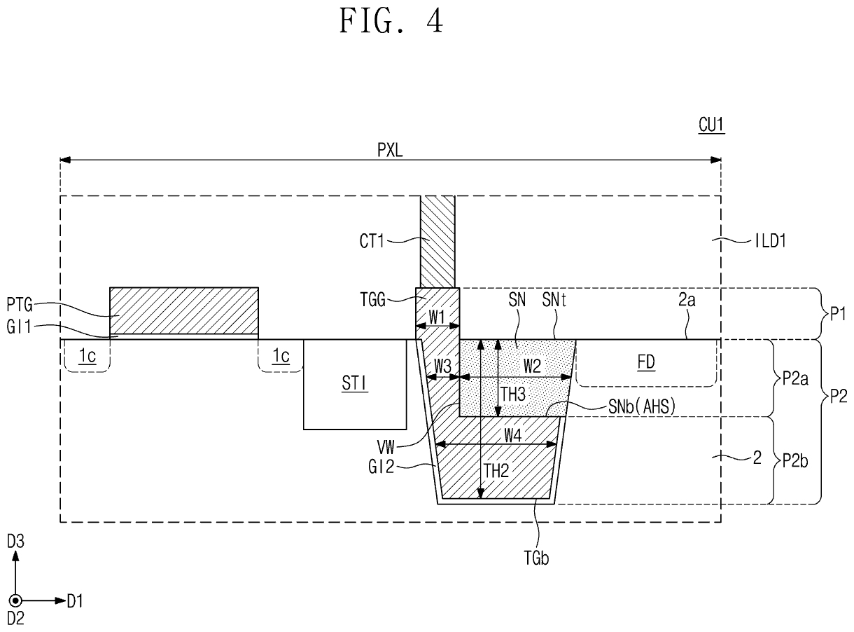

Hereinafter, an explanation of transfer gate electrode TGG, which is part of the transfer transistor TG, will now be provided. The transfer gate electrode TGG may be provided on (or at) the first surface 2a. The transfer gate electrode TGG may overlap the photodiode PD in the third direction D3. A protective pattern SN may be disposed on (or at) the first surface 2a. The protective pattern SN may penetrate a portion of the transfer gate electrode TGG. A second gate insulating pattern GI2 may be interposed between the transfer gate electrode TGG and the substrate 2. Details regarding the transfer gate electrode TGG and the protective pattern SN will be described in detail with reference to FIG. 4. For example, the transfer gate electrode TGG and the protective pattern SN may be formed within a trench formed in the substrate at the first surface 2a.

For each set of four pixel regions PX, the floating diffusion region FD may be surrounded by the protective patterns as shown in FIG. 1.

First to third interlayer insulating layers ILD1, ILD2, and ILD3 and a passivation layer PL may be sequentially stacked on the first surface 2a of the substrate 2. Each of the first to third interlayer insulating layers ILD1, ILD2, and ILD3 may include, for example, at least one of silicon oxide, silicon nitride, and silicon oxynitride. The passivation layer PL may include, for example, silicon nitride.

A first connection contact CT1 and a second connection contact CT2 may penetrate the first interlayer insulating layer ILD1. The first connection contact CT1 may be connected to the transfer gate electrode TGG. The second connection contact CT2 may be connected to the floating diffusion region FD. First metal wirings M1 and second metal wirings M2 may be provided in the second interlayer insulating layer ILD2 and the third interlayer insulating layer ILD3, respectively. The first connection contact CT1, the second connection contact CT2, the first metal wirings M1, and the second metal wirings M2 may include a conductive material such as a metal.

A fixed charge layer 40 may be disposed on the second surface 2b of the substrate 2. The fixed charge layer 40 may be formed of a metal oxide layer or a metal fluoride layer containing an amount of oxygen or fluorine less than the stoichiometric ratio. As a result, the fixed charge layer 40 may have a negative fixed charge. The fixed charge layer 40 may be made of a metal oxide or metal fluoride including at least one metal selected from the group consisting of hafnium (Hf), zirconium (Zr), aluminum (Al), tantalum (Ta), titanium (Ti), yttrium, and lanthanide. Hole accumulation may occur around the fixed charge layer 40. This may effectively reduce occurrence of dark current and white spots. Preferably, the fixed charge layer 40 may include at least one of aluminum oxide and hafnium oxide.

An anti-reflection layer 42 may be disposed on the fixed charge layer 40. The anti-reflection layer 42 may include, for example, silicon nitride.

A grid 45 may be provided on the anti-reflection layer 42. The grid 45 may overlap the separation structure DTI in some regions, but may not overlap with the separation structure DTI in other regions. The grid 45 may include a first material pattern 44 and a second material pattern 46. The first material pattern 44 may include a material that does not transmit light, for example, titanium. The first material pattern 44 and the second material pattern 46 may prevent crosstalk between adjacent pixels. The second material pattern 46 may include an organic material. The second material pattern 46 may have a refractive index of about 1.3 or less, for example.

A color filter CF1 to CF3 may be disposed on the anti-reflection layer 42. The color filter CF1 to CF3 may include a photoresist material to which a dye or pigment is added. In this case, the color filters CF1 to CF3 disposed in each of the different pixel groups GRP1 to GRP4 have different colors and may be configured in a Bayer pattern.

Microlenses ML may be disposed on the color filters CF1 to CF3. The Microlenses ML may have a convex shape and may have a certain radius of curvature. Although not illustrated, according to some embodiments, color filters of the same color may be disposed on the pixel groups GRP1 to GRP4. In this case, color filters of different colors may be disposed on other pixel groups including 16 adjacent pixel regions PX.

FIG. 4 is an enlarged view of portion ‘CU1’ in FIG. 2. Any description overlapping with the descriptions of FIGS. 1 to 3 may be omitted.

Referring to FIG. 4, a transfer gate electrode TGG according to some embodiments of the inventive concept may include (or divided into) a first portion P1 disposed on (above) a first surface 2a and a second portion P2 disposed below the first surface 2a. The first portion P1 may have a shape protruding from the substrate 2 and the second portion P2. The second portion P2 may extend into the substrate 2. The first and second portions P1 and P2 may constitute a continuous body. The second portion P2 may be closer than the first portion P1 to the second surface 2b of the substrate 2. In a cross sectional view along a line perpendicular to the second surface 2a of the substrate a, the first portion P1 may have an asymmetric shape with respect to a center axis of the trench. The center axis of the trench extends perpendicular to the second surface 2b of the substrate 2. Additionally, in the cross sectional view, the second portion P2 has a symmetric shape with respect to the center axis of the trench.

A protective pattern SN may be disposed to penetrate a portion of the transfer gate electrode TGG. The protective pattern SN may be disposed on the second portion P2 of the transfer gate electrode TGG, below the first surface 2a. In this case, the second portion P2 of the transfer gate electrode TGG may include (or divided into) a first sub-portion P2a and a second sub-portion P2b. The first sub-portion P2a may be a portion of the second portion P2 that is positioned at the same vertical level as the protective pattern SN. The second sub-portion P2b may be a portion of the second portion P2 that is disposed below the protective pattern SN. The first sub-portion P2a and the second sub-portion P2b may be connected as an integral body. The substrate 2 may have a trench, within which the transfer gate electrode TGG is disposed. The transfer gate TG and the protective pattern SN may fill the trench. The transfer gate may have a recessed corner, which includes a vertical wall VW and an adjacent horizontal surface AHS. The protective pattern SN may be in contact with the vertical wall VW and the adjacent horizontal surface AHS.

An upper surface SNt of the protective pattern SN may be exposed from (with respect to) the transfer gate electrode TGG. The first portion P1 of the transfer gate electrode TGG be exposed with respect to the protective pattern SN. The first interlayer insulating layer ILD1 may cover the upper surface SNt of the protective pattern SN. As the transfer gate electrode TGG does not cover the upper surface SNt of the protective pattern SN, a distance between the transfer gate electrode TGG and the floating diffusion region FD may be stably secured, and a width of the pixel gate electrode PTG may be increased. The protective pattern SN may have a trapezoidal shape when viewed in a cross-sectional view. As shown in FIG. 1, the protective pattern SN may have a banded shape when viewed in a plan view.

A vertical level of a lower surface TGb of the transfer gate electrode TGG may be lower than a vertical level of a lower surface SNb of the protective pattern SN. Accordingly, charge transfer capability of the transfer gate electrode TGG may not be limited. The vertical level of the lower surface SNb of the protective pattern SN may be higher than a vertical level of a lower surface of the device isolation portion STI. The vertical level of the lower surface SNb of the protective pattern SN may be adjacent to the vertical level of the lower surface of the device isolation portion STI rather than a level of the first surface 2a. The vertical level of the lower surface SNb of the protective pattern SN may be positioned below a lower surface of the floating diffusion region FD. In the present specification, the lower surface of the floating diffusion region FD may correspond to the lowest region of the floating diffusion region FD. The protective pattern SN may include, for example, silicon nitride.

The first portion P1 of the transfer gate electrode TGG may have a first width W1 in the first direction D1. The protective pattern SN may have a second width W2 in the first direction D1 in the horizontal direction to the second surface 2b of the substrate 2. The first sub-portion P2a of the transfer gate electrode TGG may have a third width W3 in the first direction D1 in the plane extending parallel to the second surface 2b of the substrate 2. The second sub-portion P2b of the transfer gate electrode TGG may have a fourth width W4 in the first direction D1. The second width W2 may correspond to a distance between the transfer gate electrode TGG and the floating diffusion region FD in the first direction D1. The widths W1 to W4 may be measured in a cross sectional view along a line perpendicular to the second surface of the substrate. The second width W2a may be a width distance measured in the first direction.

The second width W2 may be greater than the first width W1. The second width W2 may be 3 to 4 times the first width W1. The third width W3 may be less than the first width W1. The fourth width W4 may be 1.1 to 1.3 times the second width W2. The second width W2 may be, for example, 50% or more of the fourth width W4.

For example, the first width W1 may be 80 nm to 120 nm, the second width W2 may be 240 nm to 480 nm, and the fourth width W4 may be 264 nm to 624 nm. In one embodiment, the first width W1 may be 100 nm. In one embodiment, the second width W2 may be 300 nm. In one embodiment, the fourth width W4 may be 375 nm. A length PXL of the first surface 2a in the first direction D1 in one pixel region PX may be 5 to 6 times the second width W2.

As shown in FIG. 2, the substrate 2 has a first thickness TH1 in the third direction D3. The second portion P2 of the transfer gate electrode TGG has a second thickness TH2 in the third direction D3. The second thickness TH2 may correspond to a length from the first surface 2a to one end of the transfer gate electrode TGG extending into the substrate 2. The protective pattern SN may have a third thickness TH3 in the third direction D3. The thicknesses TH1 to TH3 may be measured in a cross sectional view along a line perpendicular to the second surface of the substrate.

The second thickness TH2 may be 10% to 15% of the first thickness TH1. The third thickness TH3 may be 40% to 50% of the second thickness TH2. For example, the second thickness TH2 may be 450 nm to 500 nm, and the third thickness TH3 may be 180 nm to 250 nm. According to one embodiment, the first thickness TH1 may be 4500 nm. In one embodiment, the second thickness TH2 may be 500 nm. In one embodiment, the third thickness TH3 may be 200 nm.

As the second thickness TH2 is provided as above-described, a length of the portion where the transfer gate electrode TGG extends into the substrate 2 may be secured. As a result, transfer capability of the transfer gate electrode TGG that transfers charges to the floating diffusion region FD in the substrate 2 may be improved.

As the third thickness TH3 is provided as above-described, a distance between the transfer gate electrode TGG and the floating diffusion region FD due to the protective pattern SN may be stably secured, thereby preventing a gate-induced drain leakage (GIDL) phenomenon.

The second gate insulating pattern GI2 may be provided on a side surface and a lower surface of the second portion P2 of the transfer gate electrode TGG. A portion of the lower surface of the protective pattern SN may be in contact with the second gate insulating pattern GI2. For example, a first portion of the second gate insulating pattern GI2 provided on one side surface of the transfer gate electrode TGG may extend to the lower surface SNb of the protective pattern SN. A second portion of the second gate insulating pattern GI2 provided on the other side surface of the transfer gate electrode TGG may extend to the first surface 2a.

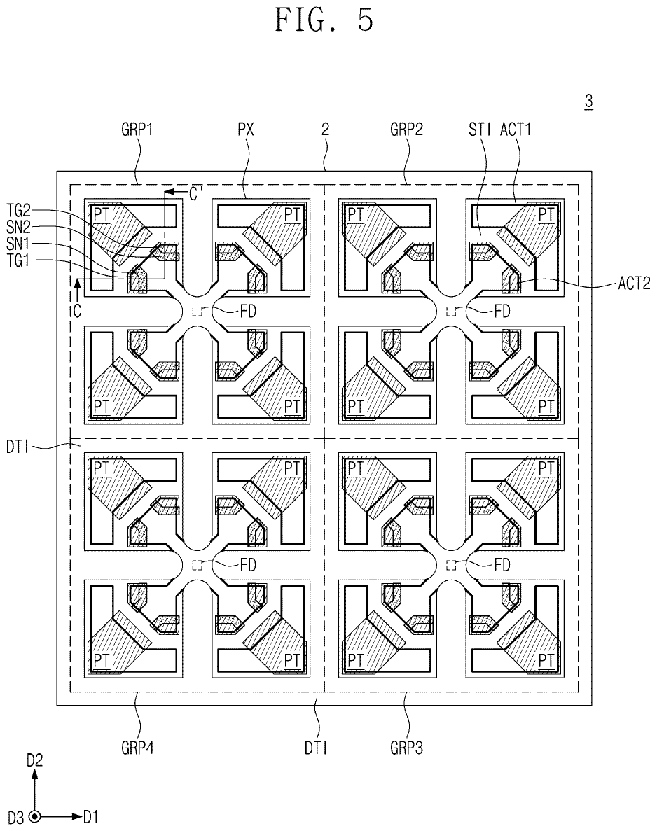

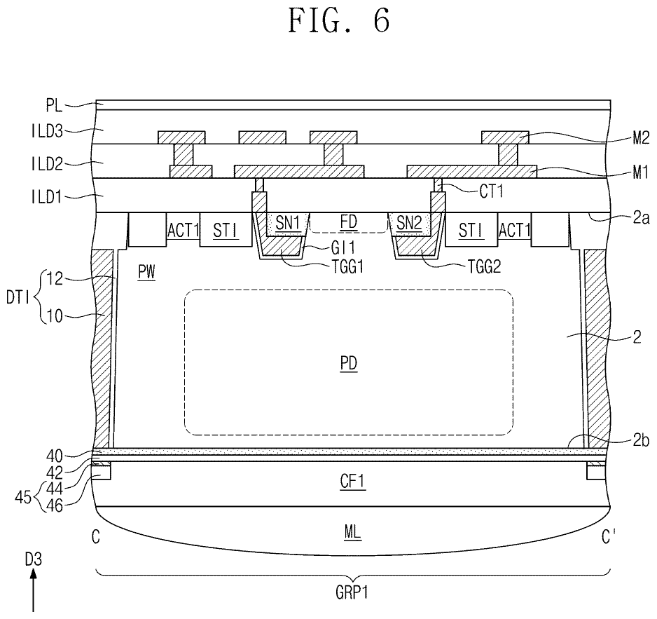

FIG. 5 is a plan view of an image sensor according to some embodiments of the inventive concept. FIG. 6 is a cross-sectional view taken along the line C-C′ of FIG. 5. Descriptions overlapping with the descriptions of FIGS. 1 to 4 may be omitted.

Referring to FIGS. 5 and 6, each of a plurality of pixel regions PX of an image sensor 3 according to some embodiments of the inventive concept may include a first transfer gate electrode TGG1, a second transfer gate electrode TGG2 disposed on second active regions ACT2, and a floating diffusion region FD provided adjacent thereto. An arrangement and a shape of the pixel transistor PT are not limited to FIG. 5, and may be variously combined and changed.

In detail, the first transfer gate electrode TGG1 and the second transfer gate electrode TGG2 may be disposed to be spaced apart from each other with the floating diffusion region FD therebetween. A first protective pattern SN1 may be disposed to penetrate a portion of the first transfer gate electrode TGG1. A second protective pattern SN2 may be disposed to penetrate a portion of the second transfer gate electrode TGG2. The first protective pattern SN1 and the second protective pattern SN2 may face each other with the floating diffusion region FD therebetween.

The configuration (e.g., shapes, relationship with other components and characteristics) of the first transfer gate electrode TGG1 and the second transfer gate electrode TGG2 may be substantially the same as that of the transfer gate electrode TGG described in FIGS. 1 to 4. The configuration (e.g., shapes, relationship with other components and characteristics) of the first protective pattern SN1 and the second protective pattern SN2 may be substantially the same as that of the protective pattern SN described in FIGS. 1 to 4.

The image sensor according to an embodiment of the inventive concept may include the floating diffusion region, the transfer gate electrode, and the protective pattern penetrating the transfer gate electrode. In this case, the width of the protective pattern may be 50% or more of the transfer gate width, and thus a distance between the transfer gate electrode and the floating diffusion region may be stably secured. As a result, a gate-induced drain leakage (GIDL), which is a phenomenon in which current leaks from the floating diffusion region by the transfer gate electrode, may be prevented, thereby improving electrical characteristics of the image sensor.

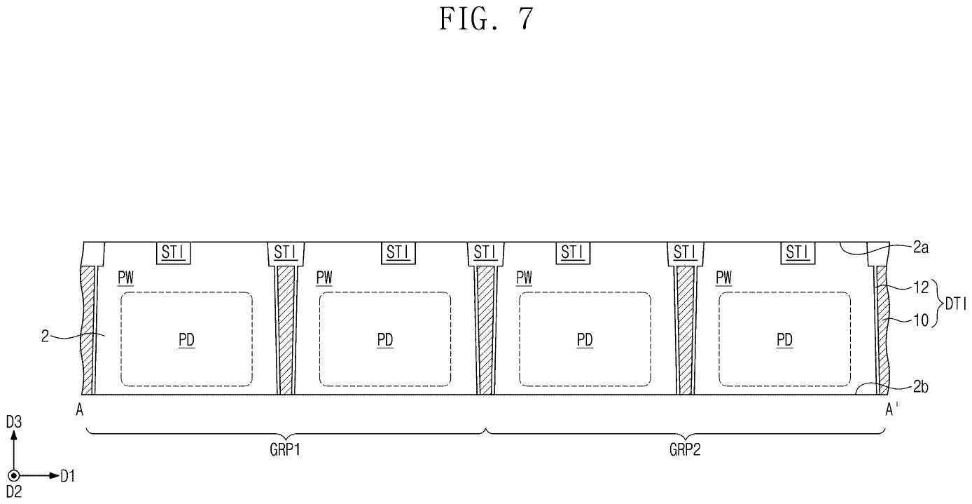

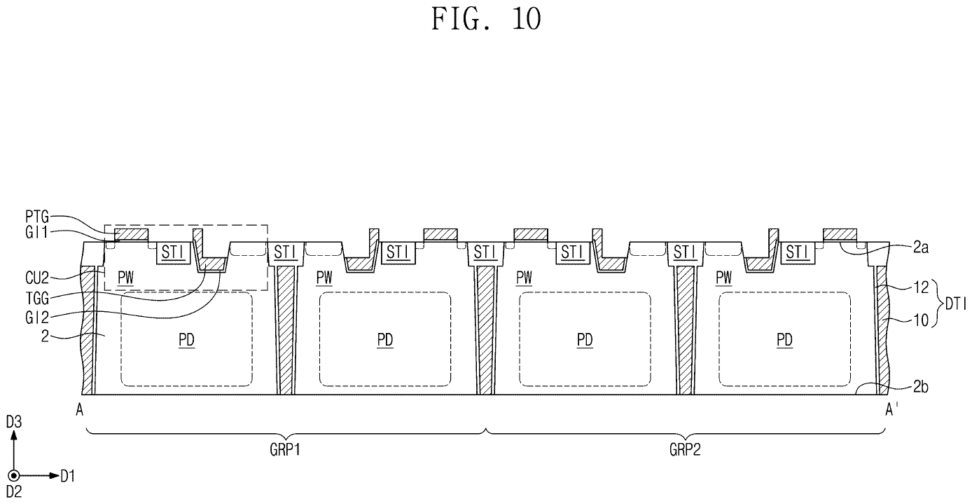

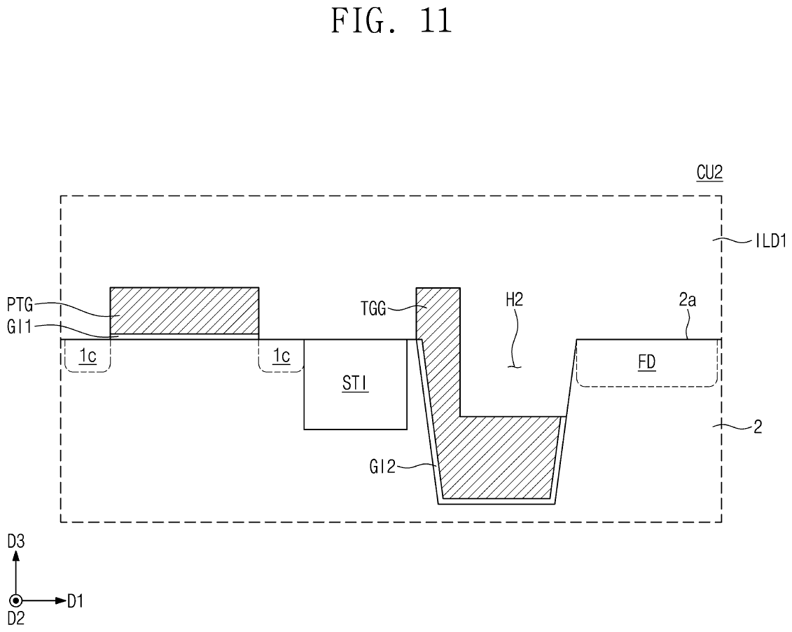

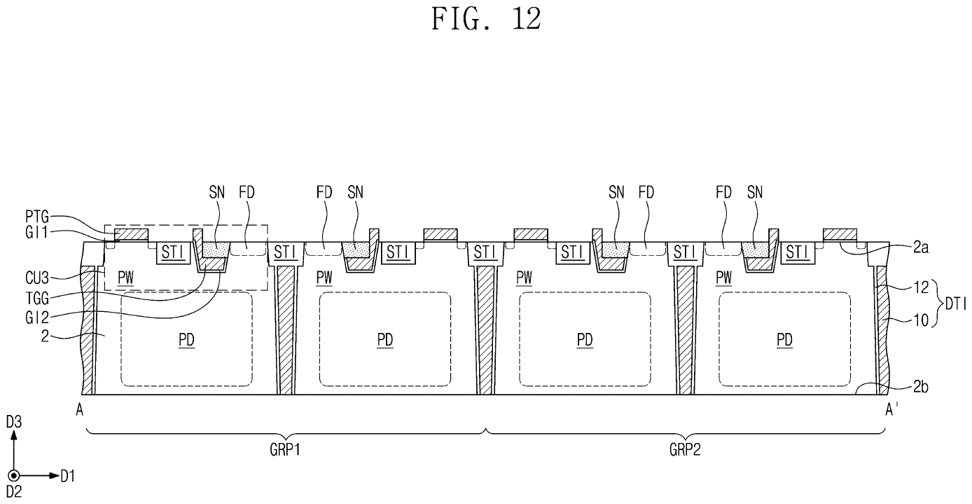

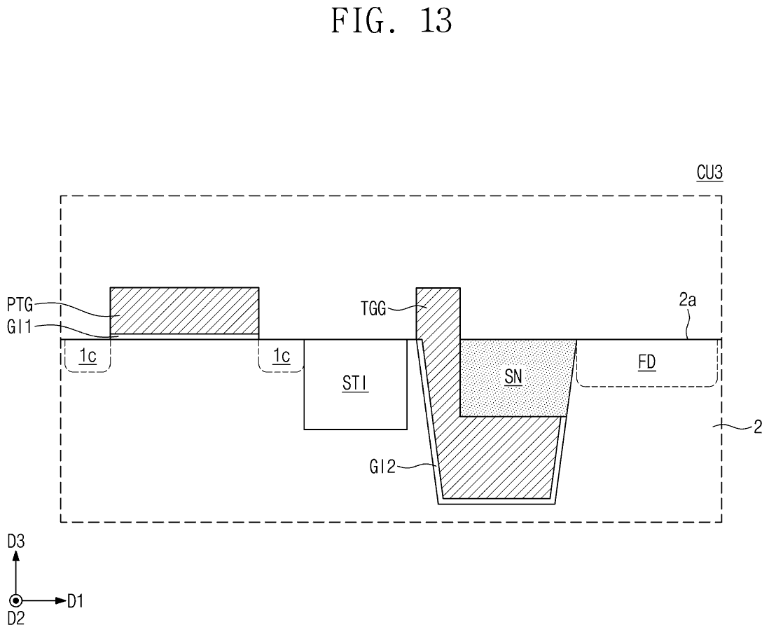

FIGS. 7, 8, 9, 10, 11, 12, and 13 are cross-sectional views illustrating a manufacturing process of an image sensor according to some embodiments of the inventive concept. In detail, FIGS. 7, 8, 9, 10, and 12 are cross-sectional views along line A-A′ of FIG. 1. FIG. 11 is an enlarged view of portion ‘CU2’ of FIG. 10. FIG. 13 is an enlarged view of portion ‘CU3’ of FIG. 12.

Referring to FIG. 1 and FIG. 7, a substrate 2 having a first surface 2a and a second surface 2b facing away from each other may be provided. The substrate 2 may have a first conductive type (e.g., P type). A device isolation portion STI may be formed on (or at) the first surface 2a of the substrate 2. The device isolation portion STI may define a first active region ACT1 and a second active region ACT2. The device isolation portion STI may be formed, for example, through a shallow trench isolation (STI) process. A separation structure DTI may be formed by penetrating the substrate 2. The separation structure DTI may include a first isolation pattern 10 and a second isolation pattern 12.

A well region PW and a photodiode PD may be formed in (or with) a substrate 2. Forming the well region PW may include injecting a first impurity into the substrate 2. Forming the photodiode PD may include injecting a second impurity different from the first impurity into the substrate 2.

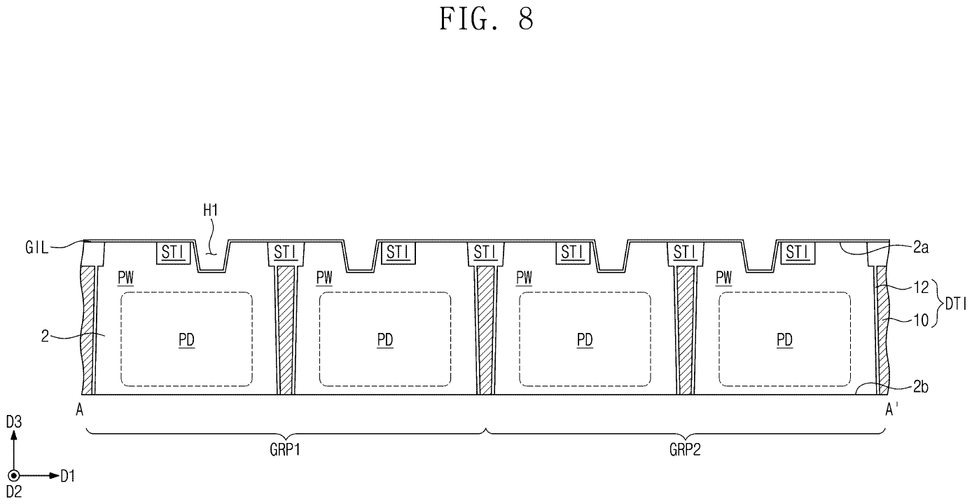

Referring to FIG. 8, a plurality of first holes (or trenches) H1 may be formed on (or at) a first surface 2a of the substrate 2. The first holes H1 may define a region where transfer gate electrodes TG of FIG. 2 are to be formed. Forming the first holes H1 may include forming a mask pattern defining a region where the first holes H1 are to be formed on the first surface 2a, etching a portion of the substrate 2 using the mask pattern as an etching mask, and removing the mask pattern. Thereafter, a gate insulating layer GIL covering the first surface 2a of the substrate 2 and a bottom surface and a side surface of the first holes H1 may be formed.

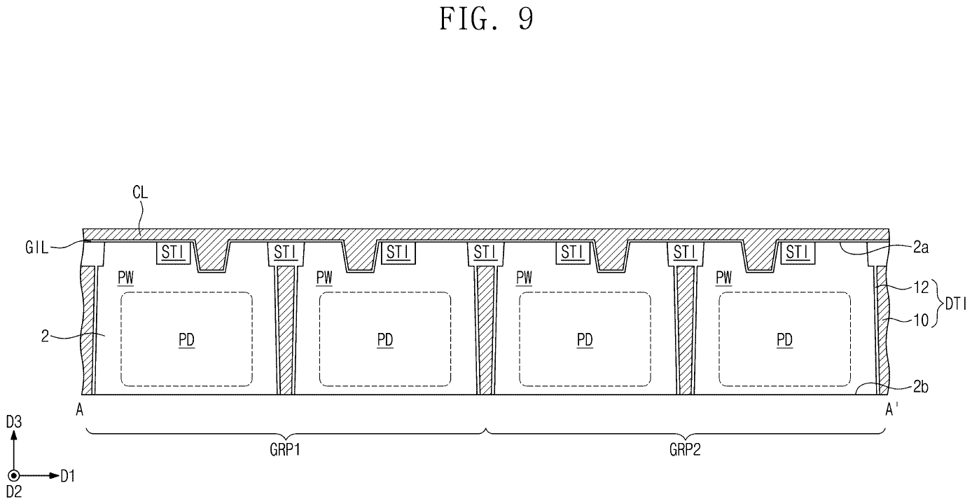

Referring to FIG. 9, a conductive layer CL may cover the first surface 2a of the substrate 2. The conductive layer CL may fill the first holes H1 formed in FIG. 8. The conductive layer CL may extend in the first direction D1 and may come into contact with the gate insulating layer GIL.

In an embodiment, the conductive layer CL may be formed of a composite layer including a plurality of layers, which are formed of conductive material.

Referring to FIGS. 10 and 11, a patterning process may be performed on the gate insulating layer GIL and the conductive layer CL. As a result of performing the patterning process, first gate insulating patterns GI1 and second gate insulating patterns GI2 may be formed from the gate insulating layer GIL. The first gate insulating pattern GI1 may be formed on the first surface 2a. The second gate insulating pattern GI2 may be formed on a bottom surface and a side surface of the first holes H1.

As a result of performing the patterning process, pixel gate electrodes PTG, transfer gate electrodes TG, and second holes (or recesses) H2 in the transfer gate electrodes TG may be formed from the conductive layer CL. The pixel gate electrodes PTG may be formed on the first gate insulating patterns GI1. The transfer gate electrodes TG may be formed on the second gate insulating patterns GI2. The second hole H2 may define a region where the protective pattern SN of FIG. 2 is to be formed. The transfer gate TG may have a recessed corner defined by the recess H2. During the second holes H2 are formed, the recessed amount of the transfer gate TG may be adjusted. Accordingly, a vertical level of an upper surface of the transfer gate electrode TGG may be variously changed to improve the performance of the image sensor.

According to some embodiments of the inventive concept, forming the second holes H2 may be performed (independently from the patterning process performed on the gate insulating layer GIL and the conductive layer CL) after the transfer gate electrodes TG are formed. In this case, forming the second holes H2 may include forming a mask pattern on the remaining region except for the region where the second hole H2 is to be formed on the first surface 2a, etching a portion of the transfer gate electrode TGG and a portion of the second gate insulating pattern GI2, and removing the mask pattern.

Thereafter, impurity regions 1c may be formed on both sides of the pixel gate electrode PTG. A floating diffusion region FD may be formed adjacent to the transfer gate electrode TGG. The impurity regions 1c and the floating diffusion region FD may be formed in the substrate 2 through an ion implantation process, etc.

Referring to FIGS. 12 and 13, protective patterns SN may be formed to fill the second holes H2 formed in FIGS. 10 and 11. A lower surface of the protective pattern SN may be in contact with the second gate insulating pattern GI2.

Forming the protective pattern SN may include, for example, forming a mask pattern on the remaining region except for the region where the protective pattern SN is to be formed, forming the protective pattern SN through an atomic layer deposition process, and removing the mask pattern. Forming the protective pattern SN may be performed until a vertical level of an upper surface of the protective pattern SN becomes the same as a vertical level of the first surface 2a. The protective pattern SN may include, for example, silicon nitride. As the protective pattern SN is formed, a distance between the transfer gate electrode TGG and the floating diffusion region FD may be secured.

In an embodiment, the protective pattern SN may be formed of a composite layer including a plurality of layers, which are formed of insulating materials.

Referring again to FIG. 2, first to third interlayer insulating layers ILD1, ILD2, and ILD3 and a passivation layer PL may be formed on the first surface 2a. A fixed charge layer 40 may be formed on the second surface 2b. An anti-reflection layer 42 may be formed on the fixed charge layer 40. A first material pattern 44 and a second material pattern 46 may be sequentially formed on the anti-reflection layer 42. A color filter CF1 to CF3 may be formed on the anti-reflection layer 42. Then, a microlens ML may be formed on the color filter CF1 to CF3, thereby completing an image sensor according to some embodiments of the inventive concept.

The image sensor according to an embodiment of the inventive concept may include the floating diffusion region, the transfer gate electrode, and the protective pattern penetrating the transfer gate electrode. In this case, the width of the protective pattern may be 50% or more of the width of the transfer gate electrode, and thus, the distance between the transfer gate electrode and the floating diffusion region may be stably secured. As a result, the gate-induced drain leakage (GIDL), which is a phenomenon in which current leaks from the floating diffusion region by the transfer gate electrode, may be prevented, thereby improving the electrical characteristics of the image sensor.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. An image sensor comprising:
a substrate comprising a first surface and a second surface opposing the first surface;
a first pixel region comprising a first photodiode;
a second pixel region comprising a second photodiode;
a separation structure between the first photodiode and the second photodiode and penetrating the substrate;
a first trench penetrating a part of the substrate from the first surface in the first pixel region;
a first transfer gate electrode comprising a first part in the first trench and a second part protruded from the first surface in the first pixel region; and
a protective pattern comprising a first surface at the same level as the first surface of the substrate and a second surface opposing the first surface of the protective pattern,
wherein a width of the first surface of the protective pattern in a first direction parallel to the first surface of the substrate in a vertical view is greater than a width of the first part of the first transfer gate electrode at the first surface in the first direction in the vertical view, and
wherein the image sensor is configured to receive light from the second surface of the substrate.

2. The image sensor of claim 1, wherein a width of the second surface of the protective pattern in the first direction in a vertical view is greater than a width of the first part of the first transfer gate electrode at a level of the second surface of the protective pattern in the first direction in the vertical view.

3. The image sensor of claim 2, wherein the width of the first surface of the protective pattern in the first direction in the vertical view is greater than a width of the second part of the first transfer gate electrode at the first surface of the substrate in the first direction in the vertical view.

4. The image sensor of claim 2, further comprising:
a floating diffusion region in the first pixel region,
wherein a height of the floating diffusion region from the first surface of the substrate in a second direction in the vertical view is less than a height of the protective pattern from the first surface of the substrate in the second direction in the vertical view, and
wherein the second direction is perpendicular to the first direction.

5. The image sensor of claim 2, wherein the width of the first surface of the protective pattern in the first direction in the vertical view is greater than the width of the second surface of the protective pattern in the first direction in the vertical view.

6. The image sensor of claim 5, wherein the first part of the first transfer gate electrode comprising a first surface at the same level as the first surface of the substrate and a second surface opposing the first surface of the first transfer gate electrode, and
wherein a width of the second surface of the first part of the first transfer gate electrode in the first direction is different from the width of the second surface of the protective pattern in the first direction.

7. The image sensor of claim 6, wherein the width of the second surface of the protective pattern in the first direction is equal to or more than 50% of the width of the second surface of the first part of the first transfer gate electrode in the first direction.

8. The image sensor of claim 7, further comprising:
a device isolation portion in the first pixel region,
wherein a height of the device isolation portion from the first surface of the substrate in a second direction in the vertical view is different from the height of the protective pattern from the first surface of the substrate in the second direction in the vertical view, and
wherein the second direction is perpendicular to the first direction.

9. The image sensor of claim 8, further comprising:
a floating diffusion region in the first pixel region,
wherein the floating diffusion region, the protective pattern, and the device isolation portion are sequentially arranged in the first direction in the vertical view.

10. The image sensor of claim 2, wherein the width of the first part of the first transfer gate electrode at the first surface in the first direction in the vertical view is equal to or less than 50% of the width of the first surface of the protective pattern in the first direction in the vertical view.

11. The image sensor of claim 10, further comprising:
a second transfer gate electrode in the first pixel region.

12. An image sensor comprising:
a substrate comprising a first surface and a second surface opposing the first surface;
a first pixel region comprising a first photodiode;
a second pixel region comprising a second photodiode;
a third pixel region comprising a third photodiode;
a fourth pixel region comprising a fourth photodiode;
a floating diffusion region configured to store charges generated by the first to fourth photodiodes;
a separation structure separating the first to fourth photodiodes to each other and penetrating the substrate;
a first trench penetrating a part of the substrate from the first surface in the first pixel region;
a first transfer gate electrode comprising a first part in the first trench and a second part protruded from the first surface in the first pixel region; and
a protective pattern comprising a first surface at the same level as the first surface of the substrate and a second surface opposing the first surface of the protective pattern,
wherein a width of the first surface of the protective pattern in a first direction parallel to the first surface of the substrate in a vertical view is greater than a width of the first part of the first transfer gate electrode at the first surface in the first direction in the vertical view,
wherein the first to fourth photodiodes are sequentially arranged in a clockwise direction in a plan view, and
wherein the image sensor is configured to receive light from the second surface of the substrate.

13. The image sensor of claim 12, further comprising:
a single color filter on the first to fourth photodiodes.

14. The image sensor of claim 13, wherein a width of the second surface of the protective pattern in the first direction in a vertical view is greater than a width of the first part of the first transfer gate electrode at a level of the second surface of the protective pattern in the first direction in the vertical view.

15. The image sensor of claim 14, wherein the width of the first surface of the protective pattern in the first direction in the vertical view is greater than a width of the second part of the first transfer gate electrode at the first surface of the substrate in the first direction in the vertical view.

16. The image sensor of claim 14, wherein the width of the first part of the first transfer gate electrode at the first surface in the first direction in the vertical view is equal to or less than 50% of the width of the first surface of the protective pattern in the first direction in the vertical view.

17. The image sensor of claim 16, further comprising:
a second transfer gate electrode in the first pixel region.

18. The image sensor of claim 17, further comprising:
a device isolation portion in the first pixel region,
wherein the floating diffusion region, the protective pattern, and the device isolation portion are sequentially arranged in the first direction in the vertical view.

19. The image sensor of claim 15, further comprising:
a microlens on the first to fourth photodiodes.

20. An image sensor comprising:
a substrate comprising a first surface and a second surface opposing the first surface;
a first pixel region comprising a first photodiode;
a second pixel region comprising a second photodiode;
a separation structure between the first photodiode and the second photodiode and penetrating the substrate;
a first trench penetrating a part of the substrate from the first surface in the first pixel region;
a first transfer gate electrode comprising a first part in the first trench and a second part protruded from the first surface in the first pixel region; and
a protective pattern comprising a first surface at the same level as the first surface of the substrate and a second surface opposing the first surface of the protective pattern,
wherein a width of the second surface of the protective pattern in a first direction in a vertical view is greater than a width of the first part of the first transfer gate electrode at a level of the second surface of the protective pattern in the first direction in the vertical view, and
wherein the image sensor is configured to receive light from the second surface of the substrate.
